(19) United States
(12) Patent Application Publication
(10) Pub. No.: US 2008/0210998 A1
(43) Pub. Date: Sep. 4, 2008

(54) Method for manufacturing material layer, method for manufacturing ferroelectric capacitor using the same, ferroelectric capacitor manufactured by the same method, semiconductor memory device having ferroelectric capacitor and manufacturing method thereof

(76) Inventors: June-mo Koo, Seoul (KR); Bum-seok Seo, Yongin-si (KR); Young-soo Park, Suwon-si (KR); Jung-hyun Lee, Yongin-si (KR); Sang-min Shin, Seoul (KR); Suk-pil Kim, Yongin-si (KR)

Correspondence Address: HARNESS, DICKEY & PIERCE, P.L.C., P.O. BOX 8910, RESTON, VA, 20195, US

(21) Appl. No.: 12/068,172

(22) Filed: Feb. 4, 2008

Related U.S. Application Data
(62) Division of application No. 11/484,582, filed on Jul. 12, 2006.

(30) Foreign Application Priority Data
Jul. 13, 2005 (KR) 10-2005-0063302

(51) Int. Cl. H01L 29/92; H01L 21/8246

(52) U.S. Cl. 257/295; 438/3; 257/E27.092; 257/E29.343; 257/E21.664

(57) ABSTRACT

Provided is a method for manufacturing a material layer capable of increasing the deposition rate of a noble metal layer on a ferroelectric layer, a method for manufacturing a ferroelectric capacitor using the same, a ferroelectric capacitor manufactured by the same method, and a semiconductor memory device having the ferroelectric capacitor and a manufacturing method thereof. According to a method for manufacturing the material layer, a ferroelectric layer is formed. The ferroelectric layer may be exposed to seed plasma, and a material layer including a source material of the seed plasma may be formed on a region of the ferroelectric layer exposed to the seed plasma.

### PRIORITY STATEMENT

This application claims the benefit of Korean Patent Application No. 10-2005-0063302, filed on Jul. 13, 2005, in the Korean Intellectual Property Office, the disclosure of which is incorporated herein in its entirety by reference.

### BACKGROUND

1. Field

Example embodiments relate to a method for depositing a material layer, for example, a method for manufacturing a material layer capable of increasing the deposition rate of a noble metal layer on a ferroelectric layer, a method for manufacturing a ferroelectric capacitor using the same, a ferroelectric capacitor manufactured by the same method, and a semiconductor memory device having the ferroelectric capacitor and a manufacturing method thereof.

2. Description of the Related Art

Semiconductor devices may be roughly classified into random access memories (RAMs) having volatility and which are freely read and written, and read only memories (ROMs) having non-volatility and which are read only. Though there are various kinds of RAMs, dynamic RAMs (DRAMs) are most widely known. DRAMs may have a higher integration degree and/or higher operating speed. However, DRAMs may have disadvantages, including volatility and/or requiring periodic refreshes during operation thereof.

Recently, non-volatile memory devices maintaining the advantages of the DRAMs while omitting the disadvantages have been introduced. Such non-volatile memory devices may be classified into ferroelectric RAM (FRAM) replacing the dielectric of a capacitor of a DRAM with a dielectric having a higher dielectric constant, a magnetic RAM (MRAM) replacing a capacitor of the DRAM with a magnetic tunnelling junction cell, and a phase change RAM (PRAM) replacing a capacitor of the DRAM with a phase change layer.

Each unit cell in DRAMs and FRAMs may include one transistor and one capacitor. Therefore, DRAMs and FRAMs may have the same construction and may differ only in the volatility characteristic of data. The capacitance of the capacitor is proportional to a contact area between the electrode and the dielectric thereof and inversely proportional to the interval between the upper electrode and the lower electrode thereof. Also, the integration degrees of DRAMs and FRAMs may increase, meaning that the area on which the capacitor is formed decreases. A technique to ensure the capacitance of the capacitor while increasing the integration degrees of a DRAM and an FRAM, includes forming the capacitor as a three-dimensional structure. Therefore, a three-dimensional capacitor having a cylinder shape has been introduced. It is possible to achieve a memory device of a desired integration degree by forming a capacitor in a three-dimensional structure. However, forming of the capacitor in a three-dimensional structure means that the structure of the capacitor may be more complicated. Therefore, it may be more difficult to form a capacitor having a three-dimensional structure in higher integration DRAM and FRAM using a conventional deposition method, such as CVD.

Accordingly, an atomic layer deposition (ALD) capable of stacking a material layer in unit of an atom has been developed. Using ALD, it is possible to form a material layer having improved step coverage that cannot be achieved by conventional deposition methods and to deposit a material layer on a lower layer having a complicated structure on which the material layer cannot be formed using the conventional deposition methods.

However, problems with ALD may occur during a process of forming an electrode on ferroelectric layers formed in a three-dimensional structure.

For example, when forming an upper electrode with predetermined or desired noble metal (e.g., Ir) using ALD on a ferroelectric layer (e.g., lead zirconate titanate (PZT) layer) formed in a trench structure, the ALD may form an Ir layer on a flat region of the ferroelectric layer located between trenches but may not be able to form an Ir layer on inner sides of the trenches. That is, conventional ALD techniques may not uniformly form an upper electrode having sufficient step coverage on an entire region of the ferroelectric layer having a three-dimensional structure. An example of this problem is illustrated in FIG. 1

FIG. 1 is a scanning transmission electron microscope (STEM) photo showing an Ir layer 12 formed on a PZT layer 10 using conventional ALD.

Referring to FIG. 1, the Ir layer 12 is formed at a uniform thickness on the flat portions of the PZT layer 10 located between trenches 14 but is not formed on the inside (e.g., the inner walls and/or the bottoms) of the trenches 14. Such results mean that the Ir layer 12 is cut on the inside of the trenches 14 when the Ir layer 12 is formed on the PZT layer 10 having a trench structure using conventional ALD. In FIG. 1, a reference numeral 8 represents a lower electrode formed of Ir.

### SUMMARY

Example embodiments provide a method for manufacturing a material layer capable of increasing the deposition rate of a noble metal layer on a ferroelectric layer.

Example embodiments also provide a method for manufacturing a ferroelectric capacitor having a three-dimensional structure, capable of achieving improved step coverage of an upper electrode and/or achieving larger capacitance using any of the above methods of manufacturing a material layer.

Example embodiments also provide a ferroelectric capacitor manufactured by any of the above methods.

Example embodiments also provide a semiconductor device and a method thereof, capable of achieving higher integration and/or higher reliability by providing any of the above ferroelectric capacitors.

According to an example embodiment, there is provided a method for manufacturing a material layer, the method including: forming a ferroelectric layer; exposing the ferroelectric layer to seed plasma; and forming a material layer including a source material of the seed plasma on a region of the ferroelectric layer exposed to the seed plasma.

In an example embodiment, the ferroelectric layer may be one selected from the group consisting of a PZT layer, a lead lanthanum zirconate titanate (PLZT) layer, a strontium bismuth titanate (SBT) layer, and a barium strontium titanate (BST) layer. In an example embodiment, the material layer may be formed using atomic layer deposition (ALD). In an example embodiment, the seed plasma may be Ir plasma or SrO plasma. In an example embodiment, the material layer may be one selected from the group consisting of an Ir layer, a Ru layer, a Pt layer, a Rh layer, an SrO layer, an IrOx layer, a RuOx layer, and a RhOx layer. In an example embodiment, the seed plasma may be exposed for 5-10 seconds.

According to another example embodiment, there is provided a method for manufacturing a capacitor, the method comprising: forming a lower electrode; forming a ferroelectric layer on the lower electrode; exposing the ferroelectric layer to seed plasma; forming an upper electrode on a region of the ferroelectric layer exposed to the seed plasma, using a material layer including a source material contained in the seed plasma.

In an example embodiment, the lower electrode may be formed on a substrate where trenches having predetermined or desired depths and widths are formed such that the lower electrode covers the sidewalls and the bottoms of the trenches. In an example embodiment, the trenches each may have a width narrower than 0.39 μm. In an example embodiment, at least one of the upper electrode and the lower electrode is formed of one selected from the group consisting of Ir, Ru, Pt, Rh, SrO, IrOx, RuOx, and RhOx using ALD.

In an example embodiment, the seed plasma and the ferroelectric layer may be formed of various materials described above, and the seed plasma may be exposed for the same periods of time.

According to another example embodiment, there is provided a capacitor including: a lower electrode; a ferroelectric layer; and an upper electrode, wherein the lower electrode exists on a substrate including trenches each having predetermined or desired widths and/or depths, the lower electrode covers the sidewalls and the bottoms of the trenches, the trenches each has widths narrower than 0.39 μm, and the upper electrode covers the entire region located in the insides of the trenches of the ferroelectric layer.

In an example embodiment, a material of which at least one of the upper electrode and the lower electrode is formed and a material of which the ferroelectric layer is formed may be the same as those used in any of the above methods.

According to another example embodiment, there is provided a semiconductor memory device including: a capacitor having a lower electrode, a ferroelectric layer, and an upper electrode sequentially stacked therein; and a transistor, wherein the lower electrode exists on a substrate including trenches each having predetermined or desired widths and/or depths, the lower electrode covers the sidewalls and the bottoms of the trenches, the trenches each has a width narrower than 0.39 μm, and the upper electrode covers the entire region located in the insides of the trenches of the ferroelectric layer.

In an example embodiment, at least one of the upper electrode and the lower electrode, and the ferroelectric layer may be the same as those used in the method for manufacturing the capacitor.

According to another example embodiment, there is provided a method for manufacturing a semiconductor memory device including a capacitor and a transistor, the method including: forming a lower electrode connected to the transistor; forming a ferroelectric layer on the lower electrode; exposing the ferroelectric layer to seed plasma; forming an upper electrode on a region of the ferroelectric layer exposed to the seed plasma, using a material layer including a source material contained in the seed plasma.

In an example embodiment, the lower electrode may be formed on a substrate where trenches having predetermined or desired widths and/or depths are formed such that the lower electrode covers the sidewalls and the bottoms of the trenches. In an example embodiment, the trenches each may have a width narrower than 0.39 μm.

In an example embodiment, the upper electrode and the lower electrode may be the same as those of the semiconductor memory device. In an example embodiment, features associated with the seed plasma and/or the ferroelectric layer may be the same as those used in any of the above methods.

According to example embodiments, it is possible to form an upper electrode of noble metal on the entire exposed region of the ferroelectric layer regardless of the shape of the ferroelectric layer. Therefore, the wide contact area between the ferroelectric layer and the upper electrode may be secured, so that the capacitance of the ferroelectric capacitor may be sufficiently secured. Also, methods for manufacturing semiconductor memory devices according to example embodiments may be used to form any of the above-described ferroelectric capacitors. Therefore, because a ferroelectric capacitor having sufficient capacitance may be manufactured when methods for manufacturing the semiconductor memory device are used, the operational reliability of the resulting semiconductor memory devices may be improved.

### BRIEF DESCRIPTION OF THE DRAWINGS

The above and other features and advantages of example embodiments, will become more apparent with reference to the attached drawings in which:

FIG. 1 is a STEM photo of a conventional ferroelectric capacitor formed using ALD;

FIG. 2 is a flowchart of a method for forming a material layer according to an example embodiment;

FIGS. 3A through 3D are sectional views explaining, step by step, a method for manufacturing a material layer with reference to the flowchart of FIG. 2;

FIGS. 4A through 4D are scanning electron microscope (SEM) photos showing the results of a first experiment according to an example embodiment;

FIG. 5 is a graph illustrating showing the results of a first experiment according to an example embodiment;

FIG. 6 is a sectional view of a ferroelectric capacitor according to an embodiment an example embodiment;

FIGS. 7 through 9 are sectional views illustrating a method for manufacturing the ferroelectric capacitor of FIG. 6;

FIG. 10 is a STEM photo showing a capacitor formed in a second experiment of the present invention;

FIG. 11 is a STEM photo showing a capacitor formed in a second experiment of the present invention, in which the photo has been converted into a black/white photo to illustrate the capacitor structure more clearly;

FIGS. 12 and 13 are graphs illustrating electrical characteristics measured for a first capacitor by a method for manufacturing a dielectric capacitor according an example embodiment and a conventional second capacitor formed in a flat structure; and

FIG. 14 is a sectional view of a semiconductor memory device including a ferroelectric capacitor according to an example embodiment.

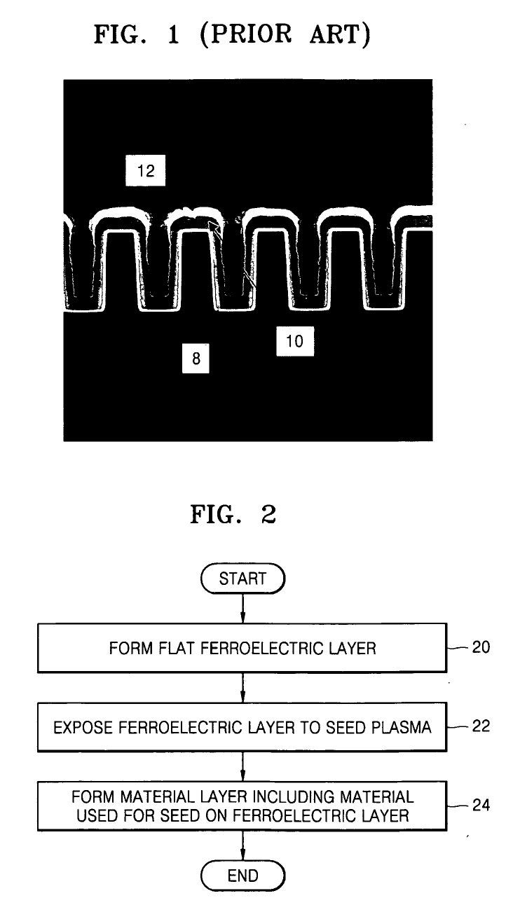

### DETAILED DESCRIPTION OF EXAMPLE EMBODIMENTS

Example embodiments will now be described more fully with reference to the accompanying drawings. In the drawings, the thicknesses of layers and regions are exaggerated for clarity. Example embodiments will now be described more fully hereinafter with reference to the accompanying drawings. This invention may, however, be embodied in many different forms and should not be construed as being limited to the example embodiments set forth herein. Rather, these example embodiments are provided so that this disclosure will be thorough and complete, and convey the scope of example embodiments to those skilled in the art. Like numbers refer to like elements throughout the specification.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-section illustrations that are schematic illustrations of example embodiments (and intermediate structures) n. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A method for manufacturing a material layer according to an example embodiment will be described below.

Referring to FIG. 2, the method may include operations 20, 22, and/or 24. Operation 20 forms a flat ferroelectric layer. In an example embodiment, the ferroelectric layer may be formed with a PZT layer. In an example embodiment, the ferroelectric layer may be formed by one selected from the group consisting of a PLZT layer, an SBT layer, a BLT layer, and a BST layer. Operation 22 exposes the ferroelectric layer to seed plasma for a predetermined or desired period of time, e.g., for 5-10 seconds. In an example embodiment, the seed plasma is plasma that uses a material, which is formed on the ferroelectric layer during a subsequent process, as a source gas. For example, when the material layer, which is formed on the ferroelectric layer during the subsequent process, is an Ir layer or an SrO layer, the seed plasma may be Ir plasma or SrO plasma. In an example embodiment, the plasma may be formed using a sputter equipment.

Operation 24 forms a material layer including a material used as the seed on a region of the ferroelectric layer exposed to the seed plasma. In an example embodiment, the material layer may be an Ir layer or the material layer may be one selected from the group consisting of a Ru layer, a Pt layer, an Rh layer, an SrO layer, an IrOx layer, a RuOx layer, and a RhOx layer.

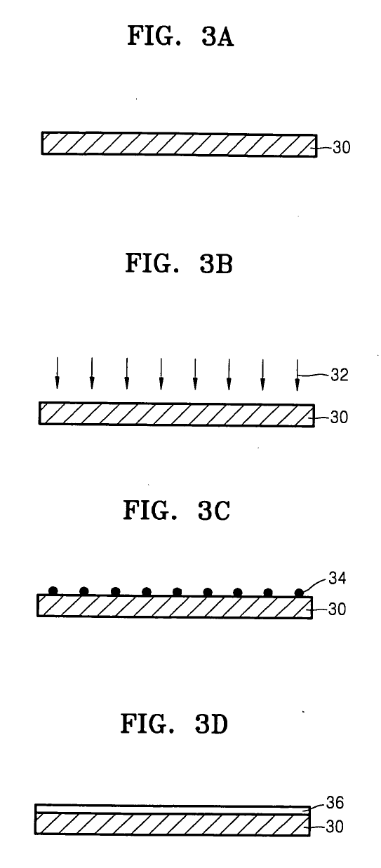

FIGS. 3A through 3D are sectional views explaining a method for manufacturing the material layer in an example embodiment.

Referring to FIGS. 3A through 3D, the upper surface of the flat dielectric layer 30 may be exposed to the seed plasma 32. While the upper surface of the dielectric layer 30 is exposed to the seed plasma 32, seeds 34 may be formed on the upper surface of the dielectric layer 30 as shown in FIG. 3C. The seeds 34 may be uniformly distributed on an entire upper surface of the dielectric layer 30 exposed to the seed plasma 32. In an example embodiment, a material which is the same as the seeds 34 may be deposited on the dielectric layer 30 using ALD. In an example embodiment, the material may be grown centering around the seeds 34. As a result, a material layer 36 having a predetermined or desired thickness may be formed on the dielectric layer 30, as shown in FIG. 3D. Though the material layer 36 may be an Ir layer, the material layer 36 may also be other layers, as described above.

A first experiment verifies the superiority of methods for manufacturing the material layer according to example embodiments. The first experiment has been performed according to the following four cases. In the first case, a silicon oxide layer was formed flat and then an Ir layer was formed on the silicon oxide layer. In the second case, an Ir layer was formed on a PZT layer that has not been exposed to seed plasma. In the third case, a PZT layer was used as a ferroelectric layer, the upper surface of the PZT layer was exposed to Ir plasma for 5 seconds, and then an Ir layer was formed on the PZT layer. In the fourth case, an Ir layer was formed in the same manner as the third case, but the upper surface of the PZT layer was exposed to Ir plasma for 10 seconds.

In the first through fourth cases, all of the Ir layers were formed for the same period of time using ALD.

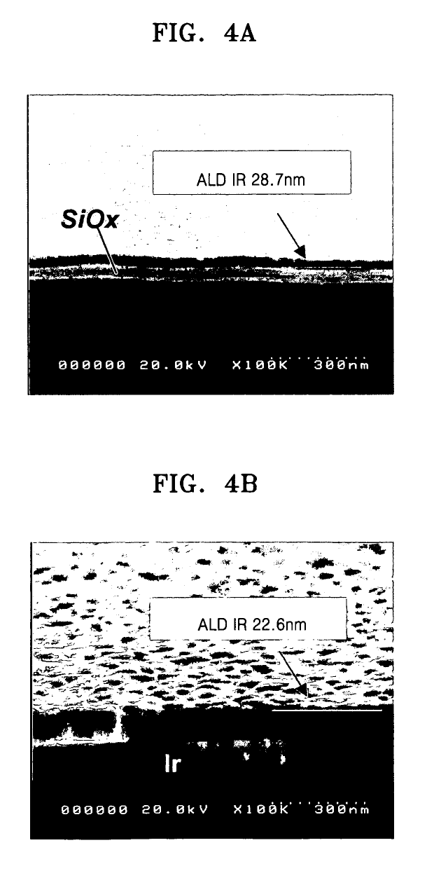

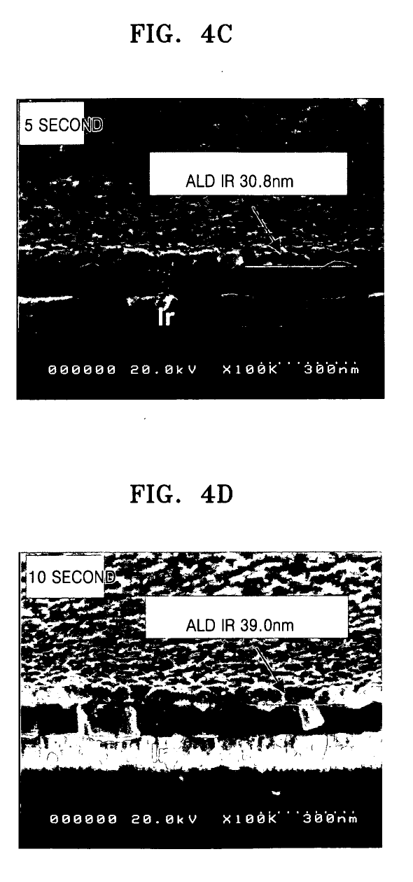

FIGS. 4A through 4D show the results of the first experiment. In these figures, ‘ALD Ir’ represents an Ir layer formed using ALD and the numerical values next to ‘ALD Ir’ represent thicknesses of the Ir layer. ‘5 seconds’ and ‘10 seconds’ shown in FIGS. 4C and 4D, respectively, represent exposure times for the Ir plasma.

FIGS. 4A through 4D show results for the first through fourth cases, respectively.

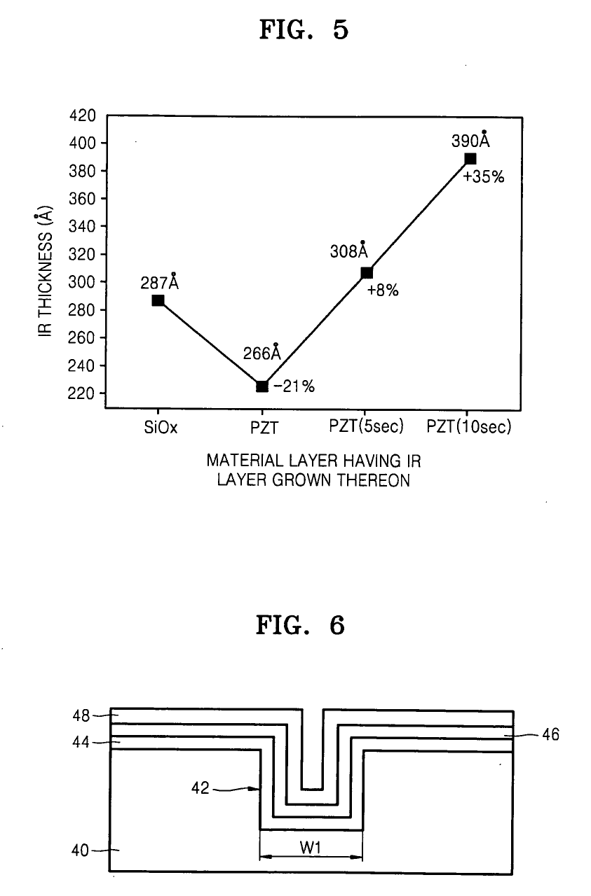

Comparison of FIG. 4A with FIG. 4B shows that the Ir layer is better formed on the SiOx layer rather than on the PZT layer that has not been exposed to the Ir plasma. However, comparison of FIG. 4A with FIG. 4C or FIG. 4D shows that the Ir layer formed on the SiOx layer has a thickness 28.7 nm and the Ir layers formed on the PZT layer exposed to the Ir plasma for 5-10 seconds have a thickness 30.8 nm and 39.0 nm, respectively. Therefore, it is revealed that the Ir layer formed on the PZT layer exposed to the Ir plasma is thicker than the Ir layer formed on the SiOx layer. Also, comparison of FIG. 4C with FIG. 4D shows that the Ir layer formed on the PZT layer is thicker as a time for which the PZT layer is exposed to the Ir plasma increases. FIG. 5 summarizes such results.

In FIG. 5, a horizontal axis denotes the type of the material layer on which the Ir oxidation layers are formed. A ‘PZT’ represents a PZT layer (referred to as a first PZT layer) not exposed to the Ir plasma. A ‘PZT (5 sec)’ and a ‘PZT (10 sec)’ represent a PZT layer (a second PZT layer) exposed to the Ir plasma for 5 seconds and a PZT layer (a third PZT layer) exposed to the Ir plasma for 10 seconds, respectively. In FIG. 5, a vertical axis represents the thickness of the Ir layer formed on the material layer.

Referring to FIG. 5, according to the first experiment, the Ir layer formed on the first PZT layer is 21% thinner than the Ir layer formed on the SiOx layer, and the Ir layer formed on the second PZT layer is 8% thicker than the Ir layer formed on the SiOx layer. Also, the Ir layer formed on the third PZT layer is 35% thicker than the Ir layer formed on the SiOx layer. When the Ir layer formed on the first PZT layer is used as a reference, the Ir layer formed on the second PZT layer is 36% thicker than the Ir layer formed on the first PZT layer, the Ir layer formed on the third PZT layer is 72% thicker than the Ir layer formed on the first PZT layer.

A capacitor according to an example embodiment, including the ferroelectric layer formed using a method for manufacturing a material layer according to example embodiments will be described with reference to FIG. 6.

Referring to FIG. 6, a trench 42 having a predetermined or desired width W1 may be formed on a substrate 40. The width W1 may be less than 0.39 μm, and may be 0.32 μm. The substrate 40 may be an insulation layer. A lower layer 44 covering the sidewalls and the bottom of the trench 44 may exist on the substrate 40. The lower layer 44 may be used as a lower electrode. Though the lower layer 44 may be an Ir layer, the lower layer 44 may be one selected from the group consisting of a Ru layer, a Pt layer, a Rh layer, an SrO layer, an IrOx layer, a RuOx layer, and a RhOx layer. A PZT layer 46, as a ferroelectric layer, may be formed on the entire region of the lower layer 44. The PZT layer 46 may be another ferroelectric layer, that is, one selected from the group consisting of a PLZT layer, an SBT layer, a BLT layer, and a BST layer. An upper layer 48 may exist on the entire region of the PZT layer 46. The upper layer 48 may be used as the upper electrode of the capacitor. The upper layer 48 may be formed of the same material as the lower layer 44, but may also be formed of a material different from the lower layer 44. Also, the upper layer 48 may be formed to completely fill the residual inner region of the trench 42 after the PZT layer 46 is formed.

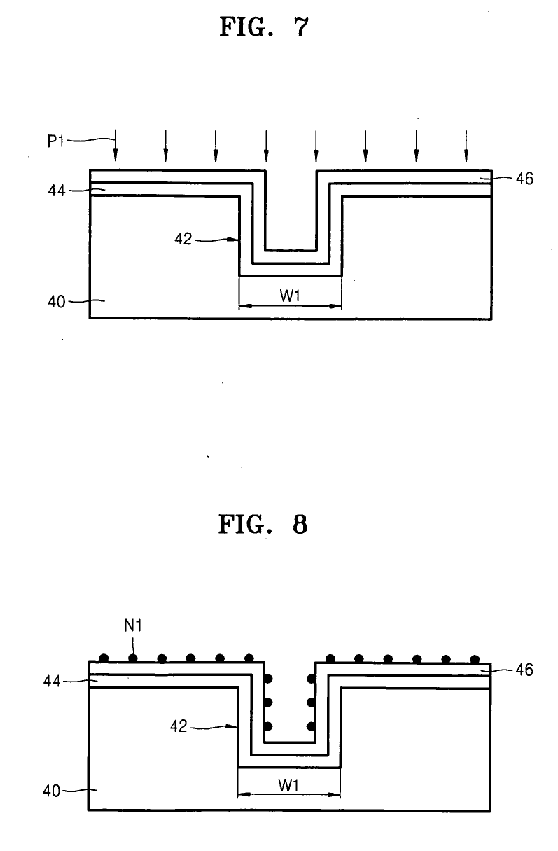

A method for manufacturing a capacitor in an example embodiment will be described with reference to FIGS. 7 through 9.

Referring to FIG. 7, a trench 42 having a predetermined or desired depth may be formed in the substrate 40. The substrate 40 may be formed using an insulation layer, e.g., a silicon oxide layer. Also, the width W1 of the trench 42 may be less than 0.39 μm, for example, 0.32 μm. After the trench 42 is formed, a lower layer 44, which may be used as a lower electrode, may be formed on the substrate 40. The lower layer 44 may be formed using ALD to cover the sidewalls and the bottom of the trench 42. The lower layer 44 may be formed using an Ir layer. The lower layer 44 may be one selected from the group consisting of a Ru layer, a Pt layer, a Rh layer, an SrO layer, an IrOx layer, a RuOx layer, and a RhOx layer.

A PZT layer 46 may be formed on the entire region of the lower layer 44. The PZT layer 46 may be formed using ALD. The PZT layer 46 may be replaced with another ferroelectric layer, that is, one selected from the group consisting of a PLZT layer, an SBT layer, a BLT layer, and a BST layer. After the PZT layer 46 is formed, the PZT layer 46 may be exposed to seed plasma P1 for a predetermined or desired time, e.g., for 5-10 seconds. The exposure time may change depending on a material which is formed on the PZT layer 46. The seed plasma P1 may be generated using a sputter, for example. The seed plasma P1 may be plasma including an element of the material layer which is formed on the PZT layer 46 during the subsequent process. For example, when the material layer is an Ir layer, the seed plasma P1 may be Ir plasma. When the material layer is an SrO layer, the seed plasma P1 may be SrO plasma.

While the PZT layer 46 is exposed to the seed plasma P1, seeds N1 may be uniformly distributed on the PZT layer 46, as illustrated in FIG. 8. The seeds N1 may include an element of the material layer which is formed on the PZT layer during a subsequent process. The seeds may be formed of Ir, SrO, Ru, or Pt. The seeds N1 may be the center of growth of the material layer, which will be formed on the PZT layer 46. Such seeds N1 may be uniformly formed also on the surface of the portions covering the sidewalls and the bottom of the trench 42 of the PZT layer 46.

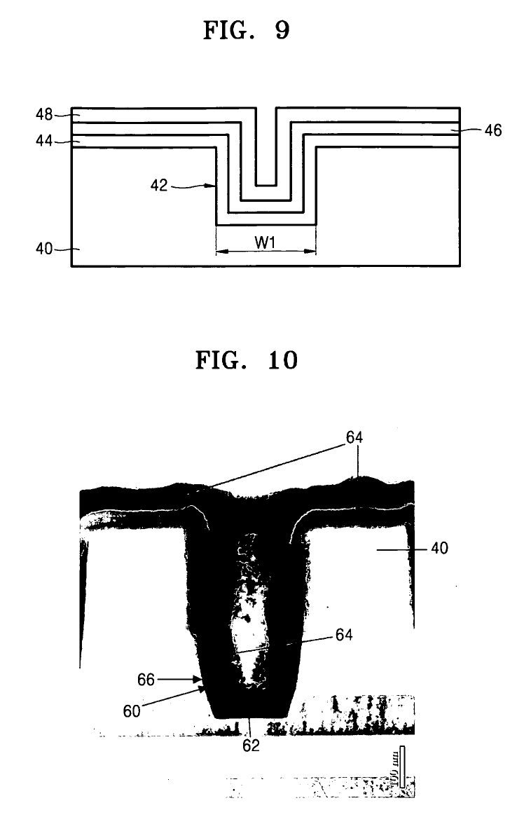

After the seeds N1 are formed, an upper layer 48 may be formed on the PZT layer 46, as illustrated in FIG. 9. The upper layer 48 may be formed using ALD. The upper layer 48 may be formed of the same material as the lower layer 44, but may be formed of a material different from the material of the lower layer 44. While the upper layer 48 is formed using ALD, a source gas (e.g., an Ir precursor gas) for forming the upper layer 48 may be supplied above the PZT layer 46. The source gas may gather and grow using the seeds N1 as the center. Referring to FIG. 8, because the seeds N1 are uniformly distributed on the entire region of the PZT layer 46, the upper layer 48 may be continuously formed on the entire region of the PZT layer 46, including the region where the trench 42 is formed.

A second experiment was performed to verify the improvement of the methods for manufacturing capacitors according to example embodiments.

In the second experiment, an actual ferroelectric capacitor was manufactured using the above-described method for manufacturing. A silicon oxide layer was used as a substrate 40 and trenches each having a diameter 0.18 μm were formed in the substrate 40. Also, a PZT layer was used as the ferroelectric layer, and an Ir layer was used as the lower and upper layers 44 and 48. Ir plasma generated with a sputtering equipment was used as the seed plasma P1. Also, the PZT layer was exposed to the Ir plasma for 10 seconds.

FIG. 10 is a STEM showing the capacitor formed in the second experiment. In FIG. 10, reference numerals 60, 62, and 64 represent a lower Ir layer used as the lower layer 44, a PZT layer, and an upper Ir layer used as the upper layer 48, respectively. Also, reference numeral 66 represents a trench formed in a silicon oxide substrate 70.

Referring to FIG. 10, the upper Ir layer 64 is formed on the portions of the PZT layer 62 in the inside of the trench 66 as well as the surroundings of the trench 66, and the upper Ir layer 64 is connected from the inside to the outside of the trench 66 without breaks.

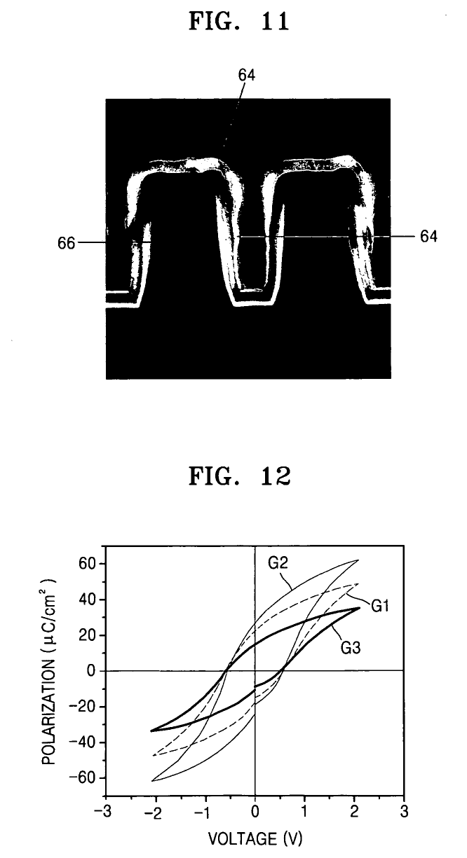

FIG. 11 is a STEM photo showing a capacitor formed in the second experiment, in which the photo has been converted into a black/white photo to illustrate the capacitor structure more clearly.

FIG. 11 more clearly shows that the upper Ir layer 64 is continuously formed without breaks inside the trench 66.

The second experiment shows that the upper Ir layer 64 is normally formed without breaks on the PZT layer 62 inside the trench 66 when the ferroelectric capacitor is formed according to example embodiments.

When the upper Ir layer 64 is formed only on the portions of the PZT layer 62 located at the surrounding of the trench 66 and is not normally formed on the portions of the PZT layer 62 located on the inside of the trench 66 in the ferroelectric capacitor in an example embodiment, the contact area between the upper Ir layer 64 and the PZT layer 62 is limited to the surroundings of the trench 66. Accordingly, an effective contact area between the upper Ir layer 64 and the PZT layer 62 may not be very different from an effective contact area between an upper electrode and a dielectric layer of a conventional capacitor having a flat structure. Thus, the electrical characteristics of both cases may not be different very much.

However, as confirmed by the second experiment, the upper Ir layer 64 is normally formed also on the portions of the PZT layer 62 formed on the inside of the trench 66 in the ferroelectric capacitor in example embodiments, so that it is expected that the electrical characteristics of the ferroelectric capacitor in example embodiments is different from that of the conventional capacitor in which a dielectric layer and electrodes are formed in a flat structure.

To confirm the above facts, a ferroelectric capacitor (referred to as a first capacitor) having a three-dimensional structure, was formed using a method for manufacturing a capacitor according to example embodiments, and manufactured another ferroelectric capacitor (referred to as a second capacitor) where a lower electrode, a ferroelectric layer, and an upper electrode are formed in a flat structure so as to make a comparison between the first capacitor and the second capacitor. Electrical characteristics of the first capacitor and the second capacitor were measured. One first capacitor had a trench width 0.25 μm and the other first capacitor had a trench width 0.32 μm.

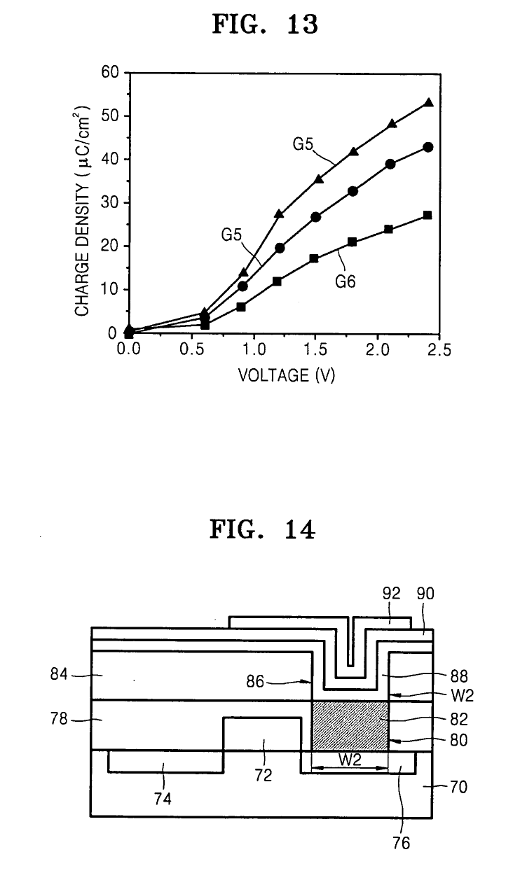

FIGS. 12 and 13 are graphs illustrating electrical characteristics measured for the first capacitor and the second capacitor.

Referring to FIG. 12, graphs G1 and G2 illustrate polarization versus voltage characteristics for the two capacitors 1 having trench widths 0.25 μm and 0.32 μm, respectively. A graph G3 illustrates polarization versus voltage characteristics for the second capacitor. The polarization versus voltage characteristics has been measured at a voltage 2.1V.

Comparison of the graph G1 with the graph G3 shows that the polarization ratio of the first capacitor having the trench width 0.25 μm is greater than that of the second capacitor. Also, comparison of the graph G1 with the graph G2 shows that the polarization ratio of the first capacitor having the trench width 0.32 μm is greater than that of the first capacitor having the trench width 0.25 μm.

From these results, it is known that the polarization ratio of capacitors of example embodiments is greater than that of the conventional capacitor and capacitors of example embodiments have a larger polarization ratio when the trench width thereof is larger.

Referring to FIG. 13, graphs G4 and G5 illustrate charge density Q versus voltage characteristics for the two capacitors 1 having trench widths 0.25 μm and 0.32 μm, respectively. A graph G6 illustrates charge density Q versus voltage characteristics for the second capacitor. The charge density versus voltage characteristics measured at a voltage 2.1 V.

Comparison of the graph G4 with the graph G6 shows that the charge density of the second capacitor is about 24 μC/cm² and the charge density of the first capacitor having the trench width 0.25 μm is 39 μC/cm², which reveals that the charge density of the first capacitor having the trench width 0.25 μm is about 60% higher than that of the second capacitor. Also, comparison of the graph G4 with the graph G5 shows that the charge density of the first capacitor having the trench width 0.25 μm is about 39 μC/cm², and the charge density of the first capacitor having the trench width 0.32 μm is about 48 μC/cm², which reveals that the charge density increases when the trench width increases.

Because the polarization ratio and the charge density are proportional to the effective contact area between the electrode and the dielectric layer of the capacitor, the above measurement results regarding the polarization ratio and the charge density verify the results of the second experiment are reasonable.

A semiconductor memory device having the ferroelectric capacitor formed using the method for manufacturing the capacitor according to example embodiments will be described below.

Referring to FIG. 14, the first impurity region 74 and the second impurity region 76, spaced apart from each other, are formed in a semiconductor substrate 70. The first and second impurity regions 74 and 76 may contain predetermined or desired conductive impurities, e.g., n-type conductive impurities implanted therein. The implanted impurities may be different depending on the type of a transistor. One of the first and second impurity regions 74 and 76 is a source region and the other is a drain region. A gate stack material 72 may be formed on the substrate 70 between the first and second impurity regions 74 and 76. The gate stack material 72 may include a gate oxidation layer and a gate electrode sequentially stacked therein. A channel connecting the first impurity region 74 with the second impurity region 76 may be formed below the gate stack material 72. The first and second impurity regions 74 and 76 and the gate stack material 72 may constitute a transistor. An interlayer insulation layer 78 covering the first and second impurity regions 74 and 76 and the gate stack material 72 may be formed on the substrate 70. The interlayer insulation layer 78 may be a silicon oxide layer or a BPSG layer. A contact hole 80 exposing the second impurity region 76 may be formed in the interlayer insulation layer 78, and the contact hole 80 may be filled with conductive plug 82. An insulation layer 84 may be formed on the interlayer insulation layer 78. The insulation layer 84 may be a silicon oxide layer. A via hole 86 exposing the conductive plug 82 may be formed in the insulation layer 84. The via hole 86 may have a diameter W2 less than 0.39 μm, for example, 0.32 μm. A lower electrode 88 may be formed on the insulation layer 84. The lower electrode 88 may cover the sidewalls and the bottom of the via hole 86. Though the lower electrode 88 may be formed of Ir, the lower electrode 88 may be formed of other noble metal besides Ir, that is, may be formed of one selected from the group consisting of Ru, Pt, Rh, SrO, IrOx, RuOx, and RhOx. A ferroelectric layer 90 may be formed on the lower electrode 88. The ferroelectric layer 90 may be formed on the entire region of the lower electrode 88 including the via hole 86. Though the ferroelectric layer 90 may be a PZT layer, the ferroelectric layer 90 may be another ferroelectric layer, that is, may be one selected from the group consisting of a PLZT layer, an SBT layer, a BLT layer, and a BST layer. An upper electrode 92 may be formed on the ferroelectric layer 90 located on the surroundings of the via hole 86. The upper electrode 92 may be also formed on the entire region of the ferroelectric layer 90 located on the inside of the via hole 86. The upper electrode 92 may be formed to fill the portion of the via hole 86 remaining after the ferroelectric layer 90 is formed. Though the upper electrode 92 may be formed of Ir, the upper electrode 92 may be formed of other noble metal as is done in the lower electrode 88.

The semiconductor memory device having the above construction may be manufactured via the following operations.

That is, the semiconductor memory device illustrated in FIG. 14 may be manufactured using the operations including: forming the transistor on the semiconductor substrate 70; forming the interlayer insulation layer 78 on the substrate 70 and forming the conductive plug 82 that passes through the interlayer insulation layer 78 and connects to the second impurity region 76; forming the insulation layer 84 on the interlayer insulation layer 78 and forming the via hole 86 (or a trench) in the insulation layer 84; and sequentially stacking the lower electrode 88, the ferroelectric layer 90, and the upper electrode 92 in the via hole 86, wherein the surface of the ferroelectric layer 90 is exposed to seed plasma that uses a material constituting the upper electrode as a seed, for a predetermined or desired time, e.g., for 5-10 seconds.

Though many details have been described with reference to example embodiments, example embodiments should be considered in descriptive sense only and not for purposes of limitation. Therefore, a person skilled in the art may form the capacitor having a three-dimensional structure using a double cylinder structure in modification of the trench structure. Also, the spirit of example embodiments may be used not only for solving the deposition problem between the ferroelectric layer and the noble metal but also for the deposition problem between other material layers besides the dielectric layer.

As described above, example embodiments may allow the upper electrode made of noble metal to be continuously formed without cutting on the exposed portions of the ferroelectric layer regardless of the geometrical shape of the ferroelectric layer. Therefore, the wide contact area between the ferroelectric layer and the upper electrode may be secured, so that the capacitance of the ferroelectric capacitor may be sufficiently secured. Also, a method for manufacturing a semiconductor memory device according to example embodiments provides the above-described ferroelectric capacitor. Therefore, because the ferroelectric capacitor having sufficient capacitance may be manufactured when the method for manufacturing the semiconductor memory device is used, the operational reliability of the semiconductor memory device may be improved.

While example embodiments has been particularly shown and described, it will be understood by those of ordinary skill in the art that various changes in form and details may be made therein without departing from the spirit and scope of the present invention as defined by the following claims.

1. A method for manufacturing a material layer, the method comprising:
forming a ferroelectric layer;
exposing the ferroelectric layer to seed plasma; and
forming a material layer including a source material of the seed plasma on a region of the ferroelectric layer exposed to the seed plasma.

2. The method of claim 1, wherein the ferroelectric layer is one selected from the group consisting of a PZT (lead zirconate titanate) layer, a PLZT (lead lanthanum zirconate titanate) layer, an SBT (strontium bismuth titanate) layer, a BLT (bismuth lanthanum titanate) layer, and a BST (barium strontium titanate) layer.

3. The method of claim 1, wherein the material layer is formed using ALD (atomic layer deposition).

4. The method of claim 1, wherein the seed plasma is Ir plasma or SrO plasma.

5. The method of claim 1, wherein the material layer is one selected from the group consisting of an Ir layer, a Ru layer, a Pt layer, a Rh layer, an SrO layer, an IrOx layer, a RuOx layer, and a RhOx layer.

6. The method of claim 4, wherein the seed plasma is exposed for 5-10 seconds.

7. A method for manufacturing a capacitor, the method comprising:
forming a lower electrode; and
manufacturing the material layer of claim 1 on the lower electrode;
wherein the material layer formed on a region of the ferroelectric layer exposed to the seed plasma is used as an upper electrode.

8. The method of claim 7, wherein the lower electrode is formed on a substrate where trenches each having a depth and a width are formed such that the lower electrode covers the sidewalls and the bottoms of the trenches.

9. The method of claim 8, wherein each of the trenches each has a width narrower than 0.39 μm.

10. The method of claim 7, wherein the upper electrode is formed of one selected from the group consisting of Ir, Ru, Pt, Rh, SrO, IrOx, RuOx, and RhOx using ALD.

11. The method of claim 7, wherein the seed plasma is Ir plasma or SrO plasma.

12. The method of claim 7, wherein the ferroelectric layer is one selected from the group consisting of a PZT layer, a PLZT layer, an SBT layer, a BLT layer, and a BST layer.

13. The method of claim 7, wherein the seed plasma is exposed for 5-10 seconds.

14.-19. (canceled)

20. A method for manufacturing a semiconductor memory device comprising:
forming a transistor;
manufacturing the capacitor of claim 7; and
wherein the lower electrode of the capacitor is connected to the transistor.

21. The method of claim 20, wherein the lower electrode is formed on a substrate where trenches having depths and widths are formed such that the lower electrode covers the sidewalls and the bottoms of the trenches.

22. The method of claim 21, wherein each of the trenches has a width narrower than 0.39 μm.

23. The method of claim 20, wherein the upper electrode is formed of one selected from the group consisting of Ir, Ru, Pt, Rh, SrO, IrOx, RuOx, and RhOx using ALD.

24. The method of claim 20, wherein the seed plasma is Ir plasma or SrO plasma.

25. The method of claim 20, wherein the ferroelectric layer is one selected from the group consisting of a PZT layer, a PLZT layer, an SBT layer, a BLT layer, and a BST layer.

26. The method of claim 20, wherein the seed plasma is exposed for 5-10 seconds.
